(19) United States
(12) Patent Application Publication
(10) Pub. No.: US 2021/0190824 A1
(43) Pub. Date: Jun. 24, 2021

(54) PROBE DETECTION DEVICE AND PANEL LIGHTING TEST DEVICE

(71) Applicant: Shenzhen China Star Optoelectronics Semiconductor Display Technology Co., Ltd., Shenzhen, Guangdong (CN)

(72) Inventor: Yaoming LUO, Shenzhen (CN)

(21) Appl. No.: 16/627,771

(22) PCT Filed: Dec. 26, 2019
(86) PCT No.: PCT/CN2019/128697

§ 371 Date: Dec. 31, 2019

(30) Foreign Application Priority Data
Dec. 18, 2019 (CN) 201911310479.8

(51) Int. Cl. G01R 1/067; G01R 31/28

(52) U.S. Cl. CPC G01R 1/06794; G01R 31/2825

(57) ABSTRACT

A probe detection device and a panel lighting test device are disclosed. The panel lighting test device includes the probe detection device including a fixture board. The fixture board has a detection end, and the detection end is provided with a data detection area and a scan data detection area. The data detection area includes a plurality of first detection keys, a plurality of first probe holes, and a plurality of first resistors. The scan data detection area includes two second detection keys, two second probe holes, and two second resistors.

### FIELD OF INVENTION

The present invention relates to the technical field of panel lighting test, and in particular, to a probe detection device and a panel lighting test device.

### BACKGROUND OF INVENTION

One process in the manufacturing of LCD panels is to conduct a first lighting test on semi-finished panels. A test method is using a pin to touch test points of the panels to drive the panels with a driving manner of short-circuit probe (shorting bar) to observe whether the panels have defects.

Please refer to FIG. 1, which is a schematic structural diagram of a panel lighting test device 90 that conducts a first lighting test on a semi-finished panel 95 in the prior art. The panel lighting test device 90 includes a signal generator 91, a signal adapter board 92, and a signal expansion board 93. A plurality of probes 94 are connected to the signal expansion board 93. The signal adapter board 92 is electrically connected to the signal generator 91, receives the signal generated by the signal generator 91, and converts the received signal. It branches out a data interface and a scan data interface, and is connected to the signal expansion board 93. The signal expansion board 93 converts a voltage signal generated by the data interface into multi-channel parallel output through the probes 94. Each channel is connected to a test point corresponding to the semi-finished panel 95 by the probes 94, and the signal in each channel is consistent.

When manufacturing a semi-finished panel, detection keys (TEG Test Keys) are made as test points on its periphery. By applying a voltage to the semi-finished panel and measuring a sheet resistance at the detection keys, a current value can be obtained by dividing a voltage value by a resistance value, and a current curve of an array substrate can be detected. By comparison and analysis, characteristics such as uniformity of the semi-finished panel can be obtained, and quality of the semi-finished panel can further be understood.

During the test process, some abnormalities often occur, causing defects of the panels to not be properly revealed. The abnormalities are as follows:

1. Parallelism between the probes and the panel does not meet standard, resulting in inconsistent contact resistances on left and right sides of the panel, which causes screen abnormality. Sometimes increasing a push-in amount of the probes can solve the problem. However, when the push-in amount is too large, the panel is at risk of being punctured.

2. A GOA probe test fixture is small and the probes thereon are dense, and the probes break during the test, causing the screen abnormality.

3. The signal from a screen signal generator is transmitted to the probes through three or four sets of the signal interfaces. If the signal interfaces are not properly plugged in or a connector is oxidized, the contact resistance will be too high and cause the screen abnormality.

Current methods for solving these abnormalities are:

1. The probes are in contact with the panel, and an amount of the probes pressing into the panel is observed with the naked eye.

2. The probes are not in contact with the panel, and breakage and deformation of the probes are observed with the naked eye.

3. The signal interfaces are repeatedly plugged and unplugged to observe whether a lighting screen is normal.

Disadvantages of these methods are:

An observation space is small, and the naked eye judgment is inaccurate. A machine has to be entered to carry out repeated checks, which take a long time. Furthermore, repeatedly plugging and unplugging the signal interfaces easily cause damage to the interfaces. This visual method cannot directly detect the resistance of the pin, and can only estimate that the resistance of the pin is too high based on the breakage or deformation of the probes. If no abnormality is found by visual inspection, the probe unit is unloaded and the resistance is measured with a multimeter.

Therefore, it is necessary to provide a new probe detection device and a panel lighting test device to overcome the problems in the prior art.

### TECHNICAL PROBLEM

The invention solves the technical problem in the prior art that whether or not the probes are normal cannot be accurately detected and thus affecting the panel lighting test. The probes do not need to be repeatedly inserted and removed and unloaded, and the resistance of the probes can be quickly and accurately detected, thereby whether or not the probes are abnormal is determined and accuracy of the panel lighting test is ensured.

### SUMMARY OF INVENTION

In order to achieve the above object, the present invention provides a probe detection device, which includes a fixture board, the fixture board has a detection end, and the detection end is provided with a data detection area and a scan data detection area.

The data detection area includes a plurality of first detection keys, a plurality of first probe holes, and a plurality of first resistors. The plurality of first detection keys is arranged in a row on the detection end. The plurality of first probe holes are arranged in a row on a side of the detection end, respectively corresponding to each first detection key, and the first detection key is exposed at a bottom of the hole. The plurality of first resistors are arranged in a row corresponding to the first detection keys respectively, one end of each of the first resistors is electrically connected to a corresponding one of the first detection keys, the other ends of the plurality of first resistors are electrically connected to each other.

The scanning data detection area includes two second detection keys, two second probe holes, and two second resistors. The two second detection keys are respectively positioned at two ends of the data detection area. The two second probe holes are provided on the side of the detection end, respectively corresponding to each second detection key, and the second detection key is exposed at a bottom of the hole. The two second resistors are respectively disposed corresponding to the second detection key, one end of each second resistor is electrically connected to each second detection key provided correspondingly, and the other ends of the two second resistors are electrically connected to each other.

Further, the first detection key and the second detection key are arranged in a row; and/or the first resistor and the second resistor are arranged in a row.

Further, the material of the first detection key and/or the second detection key includes copper.

Further, the first detection key and/or the second detection key are disposed inside the detection end.

Further, a resistance value of the first resistor and/or the second resistor is 100 Ω.

Further, the first resistor and/or the second resistor are disposed inside the detection end.

Further, the material of the fixture board includes any one of polyethylene, polypropylene, and polyvinyl chloride.

The invention also provides a panel lighting test device, including the above-mentioned probe detection device.

Further, the panel lighting test device further includes a signal generator, a signal adapter board, and a signal expansion board. Specifically, the signal generator is configured to generate an impedance detection signal. The signal adapter board is electrically connected to the signal generator and used for receiving the impedance detection signal and conducting a conversion of the impedance detection signal, and it branches out a data interface and a scan data interface. A probe is connected to the scan data interface, and the probe is electrically connected to the second detection key through the first probe hole; the signal expansion board is electrically connected to the data interface; a plurality of probes are connected to the signal expansion board, and the probes are electrically connected to the first detection key through the second probe hole.

Further, a shape and a size of the fixture board are the same as a shape and a size of a semi-finished panel detected by the panel lighting test device.

### BENEFICIAL EFFECT

The beneficial effects of the present invention are: a probe detection device and a panel lighting test device thereof are provided. By setting a dedicated probe detection device, the technical problem in the prior art that whether or not the probes are normal cannot be accurately detected and thus affecting a panel lighting test can be solved. The probes do not need to be repeatedly inserted and removed and unloaded, and a resistance of the probes can be quickly and accurately detected, thereby whether or not the probes are abnormal is determined and accuracy of the panel lighting test is ensured.

### DESCRIPTION OF DRAWINGS

FIG. 1 is a schematic structural diagram of a conventional panel lighting test device.

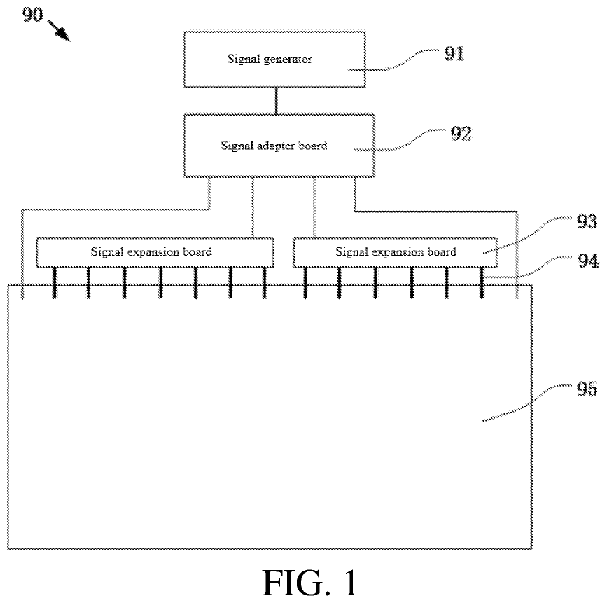

FIG. 2 is a schematic structural diagram of a probe detection device according to an embodiment of the present invention.

FIG. 3 is a schematic structural diagram of a panel lighting test device according to an embodiment of the present invention.

The components in the drawings denote as follows: 1, data detection area; 2, scan data detection area; 10, probe detection device; 11, first detection key; 12, first probe hole; 13, first resistance; 20, signal generator; 21, second detection key; 22, second probe hole; 23, second resistor; 30, signal adapter board; 31, data interface; 32, scan data interface; 40, signal expansion board; 41, first signal expansion board; 42, second signal expansion board; 50, probe; 100, panel lighting test device; 101, fixture board; 102, detecting end.

### DETAILED DESCRIPTION OF PREFERRED EMBODIMENTS

The technical solutions in the embodiments of the present application will be clearly and completely described below with reference to the accompanying drawings in the embodiments of the present application. Obviously, the described embodiments are only a part of the embodiments of the present application, but not all the embodiments. Based on the embodiments in the present application, all other embodiments obtained by those skilled in the art without creative work fall into the protection scope of the present application.

In the description of this application, it should be understood that the orientational or positional relationship indicated by the terms “center”, “longitudinal”, “transverse”, “length”, “width”, “thickness”, “upper”, “lower”, “front”, “rear”, “left”, “right”, “vertical”, “horizontal”, “top”, “bottom”, “inside”, “outside”, “clockwise”, “counterclockwise”, and the like are based on the orientation or position relationship shown in the drawings. It is only for the convenience of describing the present application and simplifying the description and does not indicate or imply that the device or element referred to must have a specific orientation, be constructed and operate in a specific orientation, and therefore cannot be understood as a limitation on the present application. In addition, the terms “first” and “second” are used for descriptive purposes only and cannot be understood as indicating or implying relative importance or implicitly indicating the number of technical features indicated. Therefore, the features defined as “first” and “second” may explicitly or implicitly include one or more of the features. In the description of the present application, the meaning of “a plurality” is two or more, unless it is specifically defined otherwise.

In the description of the present application, it should be noted that, unless otherwise specified and limited, the terms “installation”, “interconnection”, and “connection” should be understood in a broad sense, for example, they can be a fixed connection, detachable connection, or integral connection; It can be a mechanical connection, electrical connection or can communicate with each other; It can be directly connected or indirectly connected through an intermediate medium. It can be the internal connection of two elements or the interaction between two elements. For those of ordinary skill in the art, the specific meanings of the above terms in the present application can be understood according to specific situations.

In the present application, unless explicitly stated and limited otherwise, the first feature “above” or “below” the second feature may include the first feature and the second feature in direct contact, it may also include the first feature and the second feature not in direct contact but in contact through another feature between them. Moreover, the first feature “above” and “on” the second feature may include that the first feature is directly above and obliquely above the second feature, or merely indicates that the horizontal height of the first feature is greater than the second feature. The first feature “below” and “under” the second feature may include that the first feature is directly below and obliquely below the second feature, or merely indicates that the horizontal height of the first feature is less than the second feature.

The following disclosure provides various different implementations or embodiments for implementing different structures of the present application. To simplify the disclosure of the present application, the components and arrangements of specific embodiments are described below. Of course, they are merely embodiments and are not intended to limit the present application. Furthermore, the present application may repeat reference numbers and/or reference letters in different embodiments, and such repetition is for the sake of simplicity and clarity and does not indicate a relationship between the various embodiments and/or arrangements discussed. In addition, embodiments of various specific processes and materials are provided in the present application, but those of ordinary skill in the art may be aware of the application of other processes and/or the use of other materials.

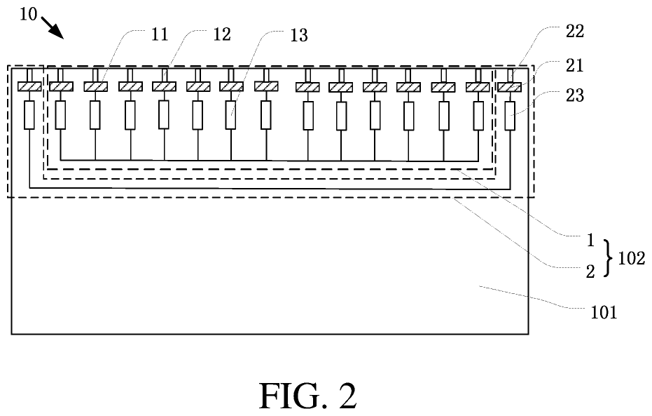

Specifically, please refer to FIG. 2, in an embodiment of the present invention, a probe detection device 10 is provided, which includes a fixture board 101 having a detection end 102, and the detection end 102 is provided with a data detection area 1 and a scan data detection area 2.

The data detection area 1 includes a plurality of first detection keys 11, a plurality of first probe holes 12, and a plurality of first resistors 13. The plurality of first detection keys 11 are arranged in a row on the detection end 102. The plurality of first probe holes 12 are arranged in a row on a side of the detection end 102, respectively corresponding to each of the first detection keys 11, and the first detection keys 11 are exposed at a bottom of the holes. The plurality of first resistors 13 are arranged in a row in one-to-one correspondence with the first detection keys 11. One end of each of the first resistors 13 is electrically connected to each of the first detection keys 11 provided correspondingly, and the other ends of the plurality of first resistors 13 are electrically connected to each other; wherein, numbers of the first detection keys 11, the first probe holes 12, and the first resistors 13 are all preferably 13.

The scan data detection area 2 includes two second detection keys 21, two second probe holes 22, and two second resistors 23. The two second detection keys 21 are respectively positioned at two ends of the data detection area 1. The two second probe holes 22 are provided on the side of the detection end 102 and are respectively corresponding to each of the second detection keys 21. The second detection keys 21 are exposed at a bottom of the holes so that an external probe can be electrically connected to the second detection keys 21. The two second resistors 23 are respectively corresponding to the second detection keys 21, one end of each of the second resistors 23 is electrically connected to a corresponding one of the second detection key 21, and the other ends of the two second resistors 23 are electrically connected to each other.

In the present embodiment, the first detection keys 11 and the second detection keys 21 are arranged in a row; and/or the first resistors 13 and the second resistors 23 are arranged in a row.

In the present embodiment, a material of the first detection keys 11 and/or the second detection keys 21 includes copper and has good electrical conductivity.

In the present embodiment, the first detection keys 11 and/or the second detection keys 21 are disposed inside the detection end 102.

In the present embodiment, a resistance of the first resistors 13 and/or the second resistors 23 is 100 Q.

In the present embodiment, the first resistors 13 and/or the second resistors 23 are disposed inside the detection end 102.

In the present embodiment, a material of the fixture board 101 includes any one of polyethylene, polypropylene, or polyvinyl chloride. It can be understood that the fixture board 101 is made of plastic or hard plastic, and has lightweight characteristics, which is convenient to handle.

In the present embodiment, a dedicated probe detection device 10 is provided to solve the technical problem in the prior art that whether or not the probes are normal cannot be accurately detected and thus affecting the panel lighting test. The probes do not need to be repeatedly inserted and removed and unloaded, and the resistance of the probes can be quickly and accurately detected, thereby whether or not the probes are abnormal is determined and the accuracy of the panel lighting test is ensured.

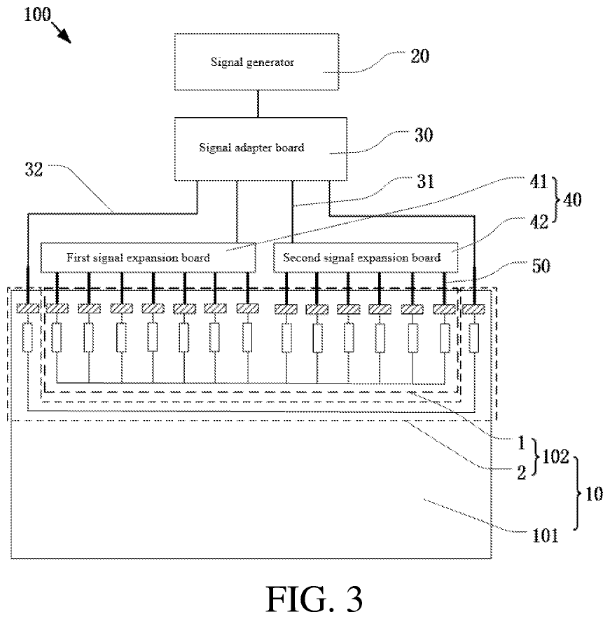

Please refer to FIG. 3, the present invention further provides a panel lighting test device 100 including the above-mentioned probe detection device 10. The panel lighting test device 100 is used to detect whether or not the probes and the connection circuit are normal.

In the present embodiment, the panel lighting test device 100 further includes a signal generator 20, a signal adapter board 30, and a signal expansion board 40. Specifically, the signal generator 20 is configured to generate an impedance detection signal. The signal adapter board 30 is electrically connected to the signal generator 20 for receiving the impedance detection signal and conducting a conversion of the impedance detection signal, and it branches out a data interface 31 and a scan data interface 32. A probe 50 is connected to the scan data interface 32, and the probe 50 is electrically connected to the second detection keys 21 through the first probe holes 12. The signal expansion board 40 is electrically connected to the data interface 31. A plurality of probes 50 are connected to the signal expansion board 40, and the probes 50 are electrically connected to the first detection keys 11 through the second probe holes 22. Preferably, the signal expansion board 40 includes a first signal expansion board 41 and a second signal expansion board 42. A number of probes 50 of the first signal expansion board 41 is preferably seven, and the number of probes 50 of the second signal expansion board 42 is preferably six.

In the present embodiment, a shape and size of the fixture board 101 are same as a shape and size of the semi-finished panel detected by the panel lighting test device 100. In this way, the fixture board 101 can be completely snapped into the panel detection area of the panel lighting test device 100. During operation, the fixture board 101 is used instead of the semi-finished panel and placed in the panel detection area of the probe detection device 10 on the worktable of the lighting machine. The signal generator is set to impedance detection, and the impedance detection sets up a dedicated model to test the resistance values between a group of probes 50 or probes 50 under conditions that the probes 50, an amount of push-in, and wiring are all normal. The detected resistance values can be directly displayed on the signal generator 20.

The following functions are implemented by subsequent tests:

1. The resistance values of the probes 50 of the first signal expansion board 41 and the resistance values of the probes 50 of the second signal expansion board 42 under two kinds of amount of push-in of probes 50 are separately detected. If the detected values are not within an error range of the standard value, the parallelism between the probes 50 and the semi-finished panel does not meet the standard, or the wiring resistance exceeds the standard.

2. The resistance values between the second detection keys 21 in the scan data detection area 2 are separately detected. If the detected values are not within the error range of the standard value, the probes 50 are broken or bent.

3. The resistance values between the second detection keys 21 in the scan data detection area 2 are separately detected. If the detected values are not within the error range of the standard value, it means that the signal interface is not plugged properly.

In this embodiment, the probe impedance detection is conducted by the panel lighting test device 100, which can quantify a status of the probes, substantially improve a speed of processing abnormalities, and reduce a loss of parts. It improves stability and effectiveness of the lighting detection system, reduces a proportion of screen abnormalities in detection, and prevents damage to parts caused by operators repeatedly plugging and unplugging the interface.

The beneficial effects of the present invention are: a probe detection device 10 and a panel lighting test device 100 thereof are provided. By setting a dedicated probe detection device 10, the technical problem in the prior art that whether or not the probes are normal cannot be accurately detected and thus affecting a panel lighting test can be solved. The probes do not need to be repeatedly inserted and removed and unloaded, and a resistance of the probes can be quickly and accurately detected, thereby whether or not the probes are abnormal is determined and accuracy of the panel lighting test is ensured.

The above are only preferred embodiments of the present invention. It should be noted that for those of ordinary skill in the art, without departing from the principles of the present invention, several improvements and modifications can be made, these improvements and modifications should also be regarded as the protection scope of the present invention.

What is claimed is:

1. A probe detection device comprising a fixture board, the fixture board having a detection end provided with a data detection area and a scan data detection area, and the data detection area comprising:
a plurality of first detection keys arranged in a row on the detection end;
a plurality of first probe holes arranged in a row on a side of the detection end, wherein the plurality of first probe holes are respectively defined corresponding to each of the first detection keys, and the first detection keys are exposed at a bottom of the first probe holes; and
a plurality of first resistors arranged in a row in one-to-one correspondence with the first detection keys, wherein one end of each of the first resistors is electrically connected to a corresponding one of the first detection key, and other ends of the plurality of first resistors are electrically connected to each other;
wherein the scan data detection area comprises:
two second detection keys respectively positioned at two ends of the data detection area;
two second probe holes provided on the side of the detection end, wherein the second probe holes are respectively defined corresponding to each of the second detection keys, and the second detection keys are exposed at a bottom of the second probe holes; and
two second resistors respectively arranged corresponding to the second detection keys, wherein one end of each of the second resistors is electrically connected to a corresponding one of the second detection keys, and other ends of the two second resistors are electrically connected to each other.

2. The probe detection device according to claim 1, wherein the first detection keys and the second detection keys are arranged in a row; and/or the first resistors and the second resistors are arranged in a row.

3. The probe detection device according to claim 1, wherein a material of the first detection keys and/or the second detection keys comprises copper.

4. The probe detection device according to claim 1, wherein the first detection keys and/or the second detection keys are disposed inside the detection end.

5. The probe detection device according to claim 1, wherein a resistance value of the first resistors and/or the second resistors is 100 Q.

6. The probe detection device according to claim 1, wherein the first resistors and/or the second resistors are disposed inside the detection end.

7. The probe detection device according to claim 1, wherein a material of the fixture board comprises any one of polyethylene, polypropylene, or polyvinyl chloride.

8. A panel lighting test device, comprising the probe detection device of claim 1.

9. The panel lighting test device according to claim 8, further comprising:
a signal generator for generating an impedance detection signal;
a signal adapter board electrically connected to the signal generator, wherein the signal adapter board is configured to receive the impedance detection signal and perform a conversion of the impedance detection signal, the signal adapter board comprises a data interface and a scan data interface, a probe is connected to the scan data interface, and the probe is electrically connected to the second detection keys through the first probe holes; and
a signal expansion board electrically connected to the data interface, wherein a plurality of probes are connected to the signal expansion board, and the plurality of probes are electrically connected to the first detection keys through the second probe holes.

10. The panel lighting test device according to claim 8, wherein a shape and a size of the fixture board are same as a shape and a size of a semi-finished panel detected by the panel lighting test device.
